(19) United States
(12) Patent Application Publication
(10) Pub. No.: US 2012/0142165 A1
(43) Pub. Date: Jun. 7, 2012

(54) Method of Avoiding Resin Outflow from the Wafer Scribe line in WLCSP

(76) Inventors: Ping Huang, Shanghai (CN); Ruisheng Wu, Shanghai (CN); Yi Chen, Shanghai (CN); Lei Duan, Shanghai (CN); Wei Chen, Shanghai (CN); Lihua Bao, Shanghai (CN)

(21) Appl. No.: 13/045,522

(22) Filed: Mar. 10, 2011

(30) Foreign Application Priority Data
Dec. 7, 2010 (CN) 201010590130.7

(51) Int. Cl. H01L 21/78

(52) U.S. Cl. 438/462; 257/E21.599

(57) ABSTRACT

A preparation process of wafer level chip scale packaging that prevents damaging a wafer in molding process is disclosed. In this process, a grinding grove is formed at a top side and around the edge of a wafer before molding is performed. The grinding groove effectively prevents the molding material from overflowing to the edge of the wafer, which avoids the damage of the wafer.

### PRIORITY CLAIM

This application claims the priority benefit of a Chinese patent application number 201010590130.7 filed Dec. 7, 2010, the entire disclosures of which are incorporated herein by reference.

### FIELD OF INVENTION

The invention relates to a preparation method of wafer level chip scale packaging for semiconductor devices, more specifically, the invention relates to a packaging method that avoids damaging the wafer in the molding process.

### TECHNOLOGICAL BACKGROUND

In a wafer level chip scale packaging WLCSP, a whole piece of wafer with IC chips formed on its top side is packaged and tested, and then IC chips are singulated. As such, the volume of each packaged chip is nearly equal to the size of the original chip.

Usually, a plurality of chips are separated from each other via wafer saw process, by cutting through the scribe lines located between the chips.

In the molding technique of the wafer level chip scale packaging, the starting molding material is in liquid phase, either liquid at room temperature or liquid after being heated, and is further solidified after cooling. In order to ensure that the molding material injected on the wafer surface has a predetermined molding density, the liquid molding material must be injected at a certain injecting pressure. However, the existence of the scribe lines cause an overflow of the liquid molding material from the scribe lines to the edge of the wafer. If the overflowed molding material connects the wafer and the clamping apparatus of a molding mould together, the wafer will be damaged once separating the clamping apparatus from the wafer after finishing molding the wafer. Furthermore, because the partial of molding material overflows from the scribe lines of the wafer to the edge, the rest of the molding material is not enough to completely cover the top side of the wafer, therefore the molding density is lower.

On the other side, in current molding technique of wafer lever chip scale packaging, the clamping apparatus is pressed at an edge of the wafer on its top side, after the clamping apparatus is removed from the wafer after finishing molding, this edge part of the wafer is still not covered by the molding material and is easily damaged when the wafer thickness is reduced, which affects on the chips adjacent to this edge.

US patent application number 6107164 discloses a wafer level chip scale packaged semiconductor apparatus and manufacturing method for the semiconductor devices, which is shown in FIGS. 1A-1D. The electrode 4 is formed on the wafer 10 and is connected to a bond pad 2 via copper interconnecting line 3. The wafer 10 with electrode 4 is cut between respective semiconductor chips by a blade 21 to define grooves 22. The wafer 10 surface with the bump electrodes 4 is totally packaged by resin 23, which is then polished by a polishing plate 24 until the bump electrode 4 is exposed. The thickness of the wafer is then reduced to a predetermined thickness by polishing the back of the wafer with a polishing blade 25. Thus, the grooves 22 are completely exposed from the back surface of the wafer 10. Solder balls are formed on the bump electrode 4. The packaged wafer 10 is then cut through the cutting groove 22 by a blade 26 to form individual chip 1 sealed with the resin. In this process, the starting resin 23 is liquid, so it easily overflows from the cutting groove 22 and connects the wafer to the molding clamping apparatus. As such, the wafer would be damaged when it is separated from the clamping apparatus and the molding material is not enough to completely cover the wafer 10.

US patent publication number 20080044984 discloses a process for forming backside illuminated devices, as shown in FIGS. 2A-2D. FIG. 2A shows an edge portion of a wafer 2 having a front side 3, a back side 5, and an edge 13. The edge trimming step is implemented prior to connecting the wafer 2 to a substrate 4. The edge 13 of the wafer 2 is trimmed into a vertical surface 20 to avoid sharp edges. The front side 3 of trimmed wafer 2 is then connected to a front side 26 of the substrate 4 through an intermediate layer 24. Alternatively, edge trimming is performed after the wafer has been bonded to the substrate. The wafer 2 is then thinned at its back side to a designed thickness using a grinding wheel 28. In this method, the poor bonding quality portion between the wafer edge and the substrate is removed by grinding. However, this method does not refer to the technique to mold a wafer in the wafer level chip scale packaging.

The present invention focuses on the following fields: molding process at wafer level, reducing overflow of molding material, preventing damage of wafer, and completely covering the edge of the wafer by molding material.

### SUMMARY OF THE INVENTION

The present invention proposes a method for avoiding damaging a wafer in the wafer molding process.

The method starts with a wafer including on its front side a plurality of semiconductor chips separating from each other with a scribe line. The top portion of the semiconductor chip includes a plurality of bond pads connecting to the internal circuit of the chip and a plurality of bump electrodes projected out of the front side of the wafer. The bump electrodes and the bond pads are electrically connected via the metal interconnected layer formed on the top portion of the semiconductor chip.

The wafer is cut along the scribe line to form a cutting groove. Then the wafer is ground at an edge at the front side of the wafer to form a grinding groove around the wafer edge. A depth of the grinding groove is deeper than a depth of the cutting groove. The front side of the wafer is then covered with a molding material with the bump electrodes also covered by the molding material. The molding material is then ground to reduce its thickness such that the bump electrodes are externally exposed from the molding material. Solder balls are then deposited on the exposed bump electrodes.

The back side of the wafer is then ground to reduce its thickness such that the cutting groove exposes at the back side of the thinned wafer. The bottom side of the semiconductor chip is then etched followed by the ion injection and laser annealing. A metal segment is then formed at the bottom side of the chip for connecting to the internal circuit of the chip. The metal segment can be formed by forming a metal layer on the back side of the thinned chip using metal vapor deposition followed with a film drying process. The dry film is pasted to the metal layer and is photo-etched. The metal layer is then photo-etched to form the metal segment.

The wafer and the molding material are then cut along the cutting groove to form a plurality of chip packages, each of which includes a semiconductor chip covering by the molding material.

These and advantages in other sides of this invention are obvious after the technician of this field reading the detail instruction of good embodiment and referring to the attachment drawings.

### BRIEF DESCRIPTION OF THE DRAWINGS

See the attached drawings to more fully describe the embodiment of the invention. However, the attached drawings are only used for description and elaboration, and they do not limit the range of the invention.

FIGS. 1A-1D are cross-sectional views illustrating a wafer level chip scale packaged semi-conductor and manufacturing method of semi-conductor of the prior art.

FIGS. 2A-2D are side views illustrating a process for forming backside illuminated devices of the prior art.

FIG. 3 is a top view schematic diagram of wafer with the semiconductor chips located on its top side.

FIG. 4 is a cross-sectional schematic diagram of wafer and local structure of the semiconductor chips.

FIG. 5 is a cross-sectional schematic diagram illustrating cutting grooves formed along the scribe line on the wafer.

FIG. 6 is a cross-sectional schematic diagram illustrating grinding wall formed by grinding the edge portion of the wafer.

FIG. 7 is a top view schematic diagram illustrating forming grinding groove at the edge portion of the wafer.

FIG. 8 is a top view schematic diagram illustrating a molding material formed in the grinding grove at the top side of the wafer.

FIG. 9 is a cross-sectional schematic diagram illustrating the clamping apparatus locating in the grinding groove with the molding material formed in the space between the wafer and the clamping apparatus.

FIG. 10 is a cross-sectional schematic diagram of the wafer covering by molding material after the clamping apparatus being removed.

FIG. 11 is a cross-sectional schematic diagram illustrating exposed bump electrodes after the molding material ground.

FIG. 12 is a cross-sectional schematic diagram illustrating forming of solder balls on the exposed bump electrodes.

FIG. 13 is a cross-sectional schematic diagram illustrating grinding at the back side of the wafer to reduce the thickness of the wafer.

FIG. 14 is a cross-sectional schematic diagram illustrating a metal film formed at the back side of the thinned wafer after performing metal vapor deposition.

FIG. 15 is a cross-sectional schematic diagram illustrating the cutting of the wafer and molding material along the exposed cutting groove.

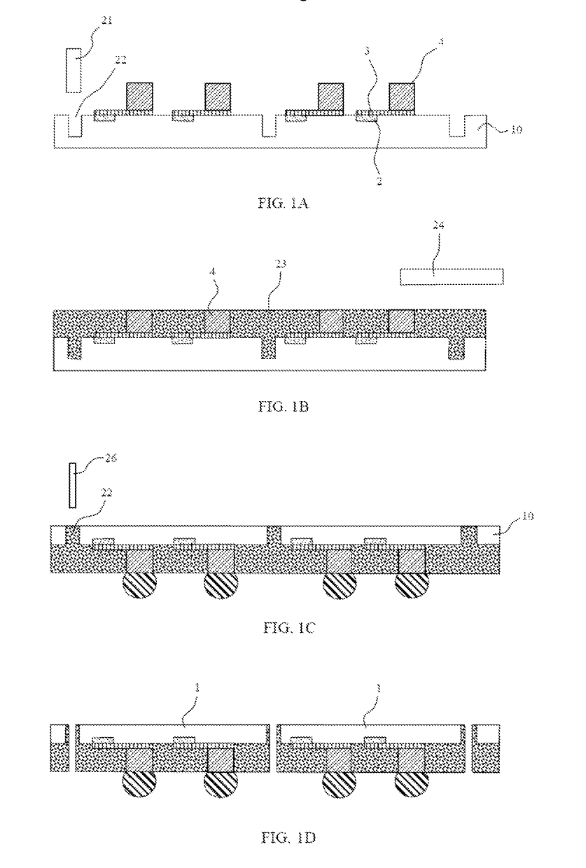

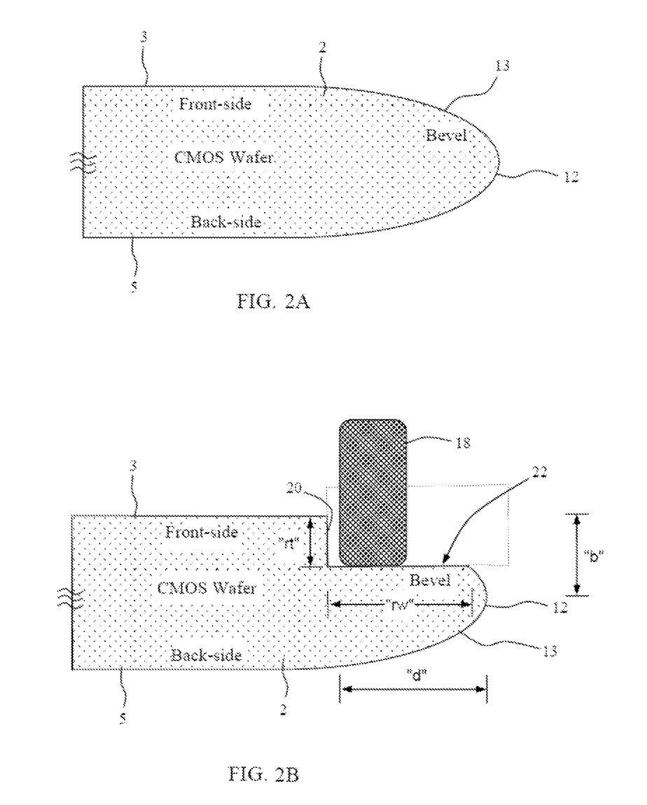

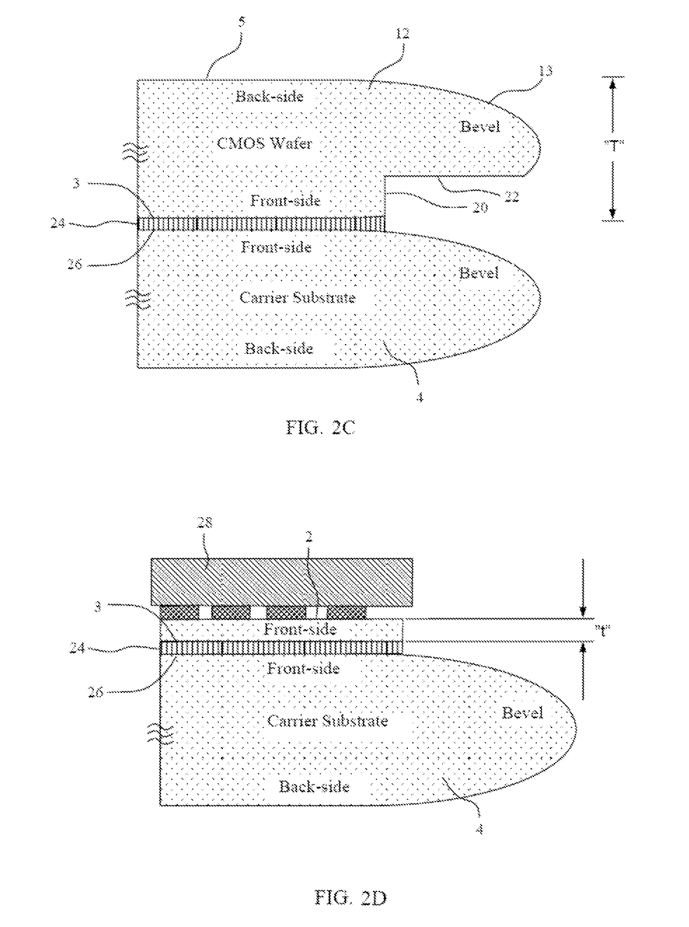

### DETAILED DESCRIPTION OF THE INVENTION

FIG. 3 is a top view of a wafer 100 having an edge 120. As shown in FIG. 3, a plurality of semiconductor chips 110 are formed on a top side 100a of the wafer 100, which are separated by a scribe line 115 located between two chips 110.

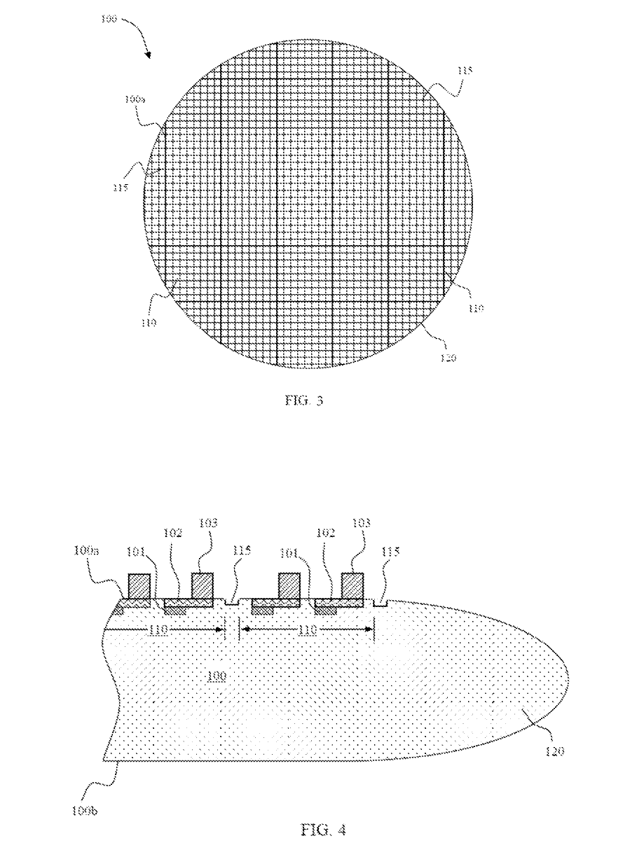

As shown in FIG. 4, integrated circuit is formed on the top side 100a of the wafer. Bond pad 101 is used as the input/output pad (I/O Pad) of the internal circuit of the chips 110, which is can be used as the port for inputting/outputting signal or Power and Ground. In the wafer level chip scale packaging, the redistribution layers technology RDL can be used for forming the bond pad at the top portion of the chip. In the wafer 100, a plurality of bond pads 101 are formed on the top portion of the chip 110, which connecting the internal circuit of the chip 110 and a plurality of bump electrodes 103 protruding out of the top side 100a of the wafer 100. By way of an example, the bond pads 101 are usually aluminum electrode. Through the RDL technology, the bond pads 101 are redistributed to form bump electrodes 103. The bump electrodes 103 are electrically connected with the bond pads 101 via the metal interconnected layer 102 deposited at the top portion of the chip 110. In RDL technology, the forming of metal interconnected layer 102 usually uses polyimide material to perform exposure and development of a photoresist and then perform metal sputtering, such as alloy layer of metal Ti/Cu.

As shown in FIG. 5, a diamond cutting knife is used to cut the wafer 100 along the scribe line 115 in FIG. 4 to form the cutting grooves 115a with a cutting depth D1, which does not completely cut and separates the chips. Referring to FIG. 3, the cutting grooves 115a extend to the edge 120 of the wafer 100.

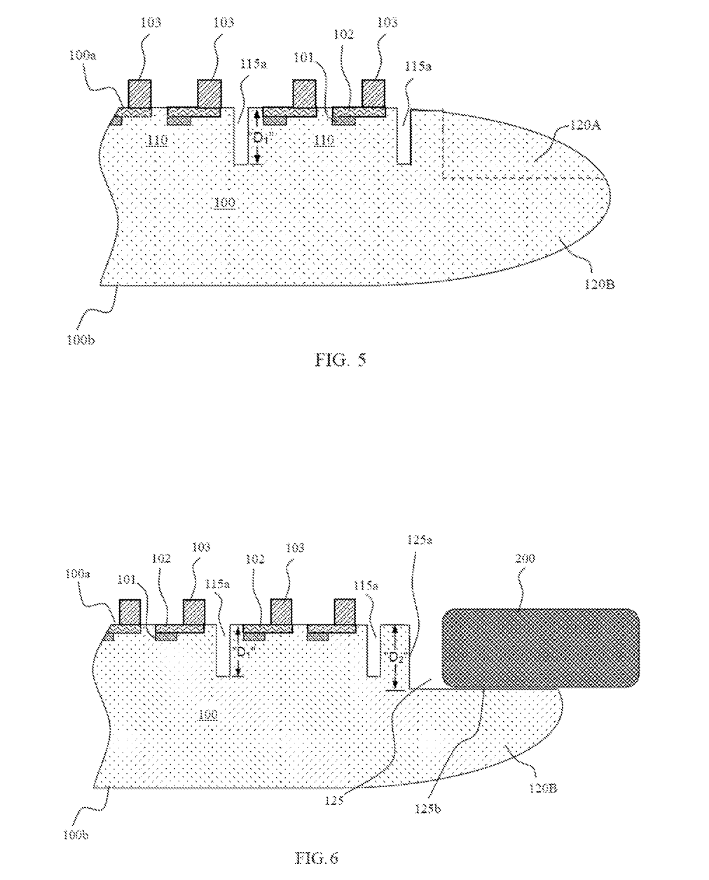

As shown in FIGS. 6 and 7, a portion around the edge and at the top side of the wafer is ground using a grinding wheel 200 to remove a portion 120A indicated by the dotted line in FIG. 5, which forms a grinding groove 125 around the edge of the wafer 100 and at the top side 100a of the wafer. The grinding groove 125 includes a sidewall surface 125a of a depth D2 and a bottom surface 125b. The portion 120B at the back side 100b of the water 100 is remained during the grinding process. The depth D₂ of the grinding groove 125 is deeper than the depth D₁ of the cutting groove 115a.

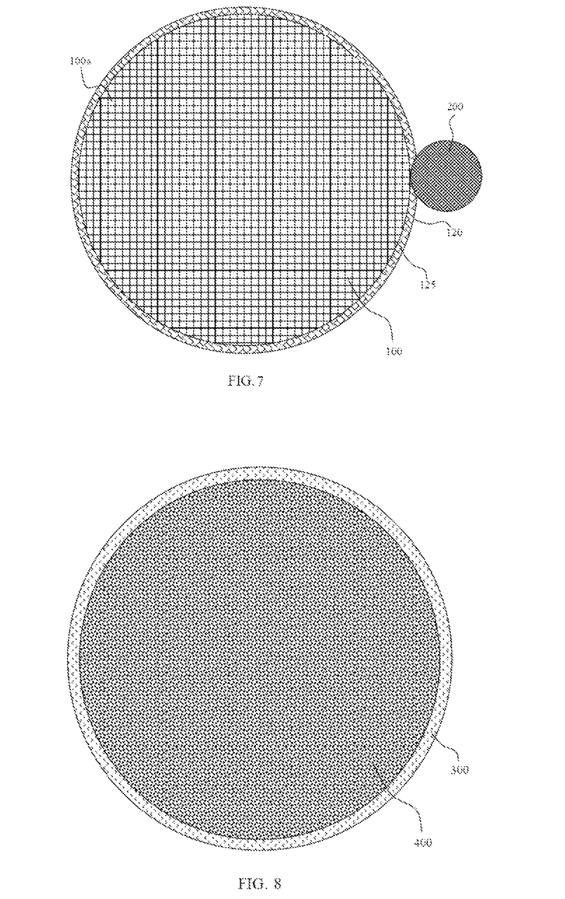

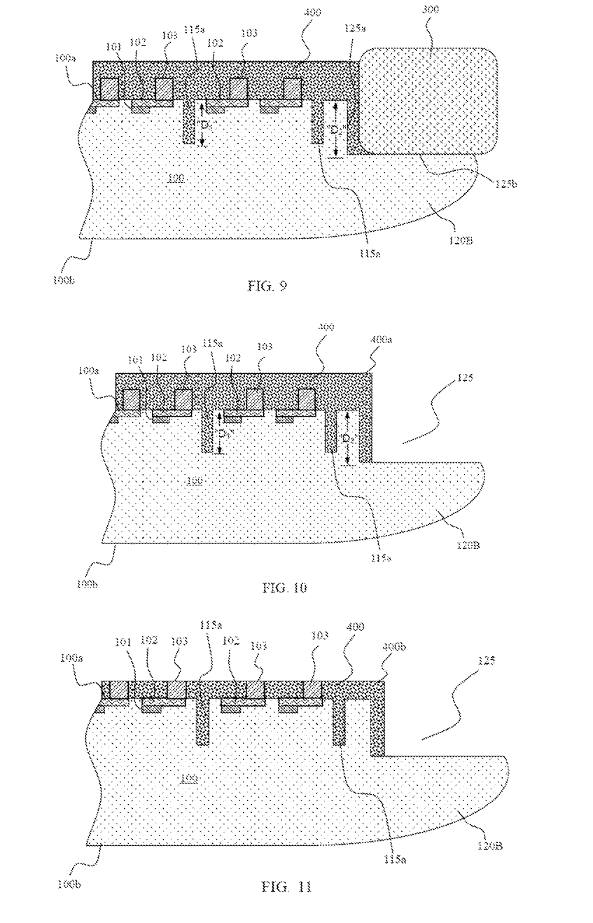

As shown in FIGS. 8-9, wafer level packaged molding process is performed. The wafer 100 is covered at the top side 100a of the wafer 100 with a molding material 400. A clamping apparatus 300, which can be a part of a molding mould (not shown), is placed in the grinding groove 125 with the bottom part of the clamping apparatus 300 pressed on the bottom surface 125b of the grinding groove 125 and an inner wall of the clamping apparatus proximity to the sidewall surface 125a with a space between the sidewall surface 125a and the inner wall of the clamping apparatus 300. The inner wall and bottom part of the clamping apparatus 300 are pasted with a tape (not-shown) to prevent the clamping apparatus 300 from directly contacting with the molding material 400. The tape is easily removed from the molding material.

The starting molding material 400 is in liquid phase, either liquid at room temperature or liquid after being heated, and is solidified after cooling. As mentioned above, because the cutting groove 115a extends to the edge 120 of the wafer 100, the liquid molding material 400 easily overflows from the cutting groove 115a to edge 120 of the wafer 100, resulting in mold bleeding. Once the mold bleeding flows to the outer area of the non-pasted tape of the clamping apparatus 300 or other parts of the molding mould, the solidified molding connects the wafer 100 with these parts together firmly, therefore, the separation of the clamping apparatus 300 from the wafer 100 will break the wafer. In addition, if the depth D2 of the grinding groove 125 is less than that of the depth D1 of the cutting groove 115a, the mold bleeding still occur.

The design scheme of grinding groove 125 of the invention avoids the mold bleeding with the mold bleeding overflowing from the cutting groove 115a being stopped in the grinding groove 125.

Furthermore, if there is no grinding groove 125, the clamping apparatus 300 will directly contact with the pre-grinding part 120A (see FIG. 5), and this pre-grinding part 120A is not covered by the molding material 400. As such, this edge part is easily damaged when the wafer thickness is reduced, and the normal die at adjacent wafer edge is further affected. However, in this invention because the pre-grinding part 120A is grinded off, edge 120 is covered by the molding material and is not damaged when wafer is ground at its back side to reduce its thickness.

As shown in FIG. 10, after the molding material 400 is solidified completely, the clamping apparatus 300 is removed from the wafer 100. The molding material 400 fully covers and packages the bump electrodes 103 and chips 110.

As shown in FIG. 11, the molding material 400 is grinded from its top surface 400a to reduce its thickness, such that the bump electrode 103 exposes at the top surface 400b of the thinned molding material 400. Solder balls 104 are attached and reflowed on the exposed bump electrode 103. As shown by FIG. 12, the solder balls 104 are formed on the bump electrode 103. By way of example, the solder ball can be made of tin (Sn). In order to achieve good bonding force, low contact resistance and oxidation resistance, and high electric conductivity between the bump electrode 103 and the solder balls 104, a bottom metal (not shown), such as alloy layer of metal Ti/Ni/Cu, is deposited on the bump electrode 103, before attaching solder balls. This metal layer can be formed by electroplating metal on the bump electrode 103, or by bump metallization (UBM) technique.

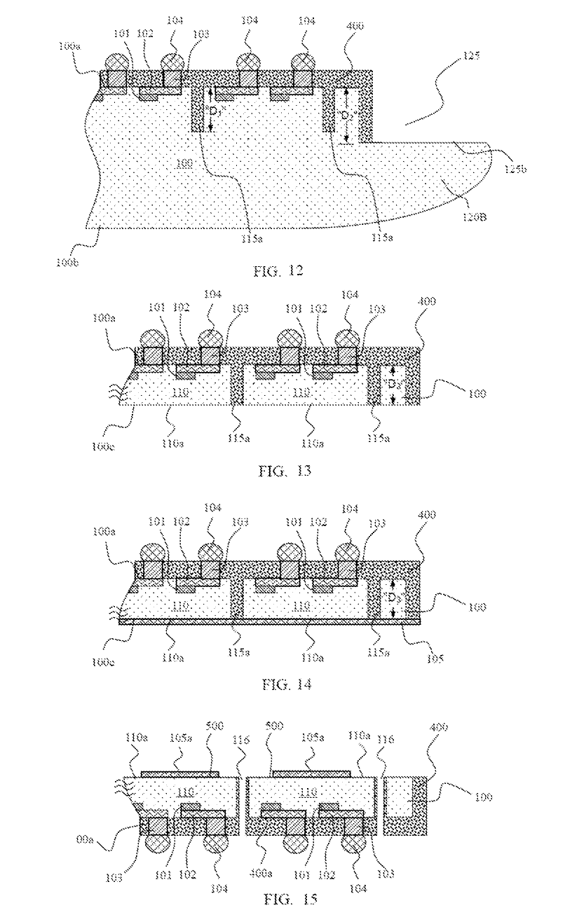

As shown in FIG. 13, the back side 100b of the wafer 100 is grinded to reduce the thickness of the wafer 100 to a thickness D3 that is shorter than D1, thus, the cutting groove 115a is exposed at the back side 100c of the thinned wafer 100. During this grinding process, the maintained portion 120B is also ground off. And after grinding the back side 100b of the wafer 100, the bottom side 110a of the chip 110 is formed at the back side 100c of thinned wafer 100 with a plurality of the chips 110 are encapsulated within the molding material 400.

As shown in FIG. 14, the bottom side 110a of the chip 110 is etched, such as wet etch, to remove the stress layer remained on the bottom side 110a, and to repair the lattice damage to the bottom side 110a of the die 110 during the grinding process. Then ion injection is conducted for the bottom side 110a of the die 110, and some lattice defects generated on the bottom side 110a of the die 110 are removed by low temperature annealing or laser annealing after injecting ion. A metal vapor deposition is then performed to form a metal layer segment of metal film 105, such as the alloy of Ti/Ni/Ag, on the back side 100c of the thinned wafer 100, followed by a film drying process. In this drying process, a layer of dry film resists is pasted on the metal film 105, and the dry film is then photo-etched. The etched dry film is then exposed and developed forming the residual dry film that only covers partial area of the metal film 105 of the bottom side 110a. The metal film 105 is then photo-etched with the residual dry film as a mask, forming the metal layer segment 105a located on the bottom side 110a of the chip 110, as shown in FIG. 15. The metal layer segment 105a located on the bottom side 110a of the chip 110 is connected with the internal circuit of the chip 110. In this step, the dry glue in the dry film is directly pasted on the metal film 105.

The wafer and the molding material 400 are cut along the cutting groove 115a forming cutting trough 116 using a diamond cutting knife to separate a plurality of packages 500, each of which includes a chip 110 covering with a molding body 400a on top and the bottom metal layer segment 105a is exposed at the back side of the thinned wafer. According to an embodiment of the invention, the chip 110 can be a vertical metal oxide semiconductor field effective transistor (MOSFET), with the metal layer segment 105a forming a drain electrode and the plurality of bond pads 101 forming a gate electrode and a source electrode.

Typical examples of specific structures adopted in concrete implementation are explained and illustrated here. Though they represent good examples of implementation, they are not intended to be exhaustive.

As for the technicians of this field, after reading above descriptions, it is obvious that there are various changes and modifications. Therefore, the attached claims shall be regarded as the total changes and modifications covering the real intention and scope of the invention. Any and all of the equivalent scope and contents in the scope of the claims shall be belonging to the intention and scope of the invention.

1. A method for avoiding damaging a wafer in a wafer molding process, comprising:
providing a wafer, wherein a front side of the wafer comprises a plurality of semiconductor chips separating to each other with a scribe line;
cutting the wafer along the scribe line to form a cutting groove;
grinding around an edge of the wafer at the front side to form a grinding groove around the edge at the front side of the wafer; and
covering the front side of the wafer with a molding material.

2. The method of claim 1, further comprising following steps:
grinding the molding material at a top surface to reduce a thickness of the molding material;
grinding at a back side of the wafer to reduce a thickness of the wafer, wherein the cutting groove exposes at the back side of the thinned wafer; and
cutting the wafer and the molding material along the cutting groove to form a plurality of chip packages, each of which comprises a semiconductor chip covering by the molding material.

3. The method of claim 1, wherein a depth of the grinding groove is deeper than the depth of the cutting groove.

4. The method of claim 2, wherein a plurality of bond pads are formed on a top portion of each semiconductor chip, wherein the bond pads connect an internal circuit of the semiconductor chip and a plurality of bump electrodes projected out of the front side of the wafer, and wherein the bump electrodes and the bond pads are electrically connected via a metal interconnected layer formed on a top portion of the semiconductor chip.

5. The method of claim 4, wherein the bump electrodes are covered by the molding material.

6. The method of claim 5, wherein the bump electrodes are externally exposed from the molding material after the molding material ground.

7. The method of claim 6, further comprising a step of depositing and reflowing solder balls on the exposed bump electrodes.

8. The method of claim 7, further comprising a step for forming a bottom layer metal on the exposed bump electrodes before depositing the solder balls.

9. The method of claim 4, after grinding at the back side of the wafer, further comprising:
etching at a bottom side of the semiconductor chip;
ion injecting and laser annealing at the bottom side of the semiconductor chip; forming a metal layer segment locating at the bottom side of the semiconductor chip, wherein the metal layer segment connects to the internal circuit of the semiconductor chip.

10. The method of claim 9, wherein forming the metal layer segment comprises:
forming a metal layer on the back side of the thinned wafer via metal vapor deposition;
performing film drying process to form a dry film on the metal layer;
photo-etching the dry film;
etching the metal layer by using dry film as a mask, wherein remaining of the metal layer locating on the bottom side of the semiconductor chip forms the metal layer segment.
